(19) United States
(12) Patent Application Publication
(10) Pub. No.: US 2024/0397750 A1
(43) Pub. Date: Nov. 28, 2024

(54) ELECTRONIC DEVICE

(71) Applicant: InnoLux Corporation, Miao-Li County (TW)

(72) Inventors: Chandra LIUS, Miao-Li County (TW); Kuan-Feng LEE, Miao-Li County (TW); Yu-Jhou GONG, Miao-Li County (TW)

(73) Assignee: InnoLux Corporation, Miao-Li County (TW)

(21) Appl. No.: 18/613,060

(22) Filed: Mar. 21, 2024

(30) Foreign Application Priority Data
Apr. 26, 2023 (CN) 202310457720.X
Sep. 5, 2023 (CN) 202311133019.9

(51) Int. Cl. H10K 59/121; H10K 59/131

(52) U.S. Cl. CPC H10K 59/1213; H10K 59/131

(57) ABSTRACT

This disclosure provides an electronic device including a substrate, a main electronic unit, an auxiliary electronic unit, a main working circuit and an auxiliary working circuit. The substrate has a first portion and a second portion bent with respect to the first portion, and the first portion includes a normal active region and a functional active region. The main electronic unit is disposed on the normal active region. The auxiliary electronic unit is disposed on the functional active region. The main working circuit is disposed on the first portion, and the main working circuit outputs a first driving signal to the main electronic unit according to a first data signal. The auxiliary working circuit is disposed on the second portion, and the auxiliary working circuit outputs a second driving signal to the auxiliary electronic unit according to a second data signal.

### BACKGROUND OF THE DISCLOSURE

### 1. Field of the Disclosure

The present disclosure relates to an electronic device, and more particularly to an electronic device having narrow border design or borderless design.

### 2. Description of the Prior Art

In the structure of the electronic device (such as the display device), the reduction of the width of the border of the electronic device is limited since the circuits or chips are disposed in the peripheral region. However, the reduction of the width of the border is still needed to achieve narrow border design or borderless design of the electronic devices nowadays. Therefore, how to effectively reduce the width of the border of the electronic device is a technical problem that needs to be solved at present.

### SUMMARY OF THE DISCLOSURE

One of the objectives of the present disclosure is providing an electronic device.

In some embodiments, the present disclosure provides an electronic device which includes a substrate, a main electronic unit, an auxiliary electronic unit, a main working circuit and an auxiliary working circuit. The substrate includes a first portion and a second portion bent with respect to the first portion, and the first portion has a normal active region and a functional active region. The main electronic unit is disposed on the normal active region. The auxiliary electronic unit is disposed on the functional active region. The main working circuit is disposed on the first portion and electrically connected to the main electronic unit, the main working circuit is configured to receive a first data signal and output a first driving signal to the main electronic unit according to the first data signal. The auxiliary working circuit is disposed on the second portion and electrically connected to the auxiliary electronic unit, the auxiliary working circuit is configured to receive a second data signal and output a second driving signal to the auxiliary electronic unit according to the second data signal.

These and other objectives of the present disclosure will no doubt become obvious to those of ordinary skill in the art after reading the following detailed description of the embodiment that is illustrated in the various figures and drawings.

### BRIEF DESCRIPTION OF THE DRAWINGS

FIG. 1 is a schematic top view diagram illustrating an electronic device according to a first embodiment of the present disclosure.

FIG. 2 is a partially enlarged top view diagram illustrating the electronic device according to the first embodiment of the present disclosure.

FIG. 3 is a schematic cross-sectional diagram illustrating the electronic device according to the first embodiment of the present disclosure along a line A-A′ and a line B-B′ in FIG. 1.

FIG. 4 is a schematic diagram illustrating cross-sectional structures of a portion of a connection line according to some embodiments of the present disclosure.

FIG. 5 is a schematic diagram illustrating anti-crack patterns of a connection line according to some embodiments of the present disclosure.

FIG. 6 is a block diagram of signal processing of the electronic device according to the first embodiment of the present disclosure.

FIG. 7 is a schematic cross-sectional diagram illustrating an electronic device according to a second embodiment of the present disclosure along a line A-A′ in FIG. 1.

FIG. 8 is a schematic diagram illustrating anti-crack patterns of a connection line according to a third embodiment of the present disclosure.

FIG. 9 is a partially enlarged top view diagram illustrating an electronic device according to a fourth embodiment of the present disclosure.

FIG. 10 is a partially enlarged top view diagram illustrating an electronic device according to a fifth embodiment of the present disclosure.

FIG. 11 is a partially enlarged top view diagram illustrating an electronic device according to a sixth embodiment of the present disclosure.

FIG. 12 is a schematic diagram illustrating the positional relationship among main working circuits, auxiliary working circuits, main gate drivers and auxiliary gate drivers according to a seventh embodiment of the present disclosure.

FIG. 13 is a schematic diagram illustrating the positional relationship among main working circuits, auxiliary working circuits, main gate drivers, auxiliary gate drivers, main emission signal drivers and the auxiliary emission signal drivers according to an eighth embodiment of the present disclosure.

FIG. 14 is a schematic top view diagram illustrating an electronic device according to a ninth embodiment of the present disclosure.

FIG. 15 is a schematic top view diagram illustrating an electronic device according to a tenth embodiment of the present disclosure.

FIG. 16 is a schematic top view diagram illustrating an electronic device according to an eleventh embodiment of the present disclosure.

FIG. 17 is an enlarged schematic diagram illustrating the area around the conductive pad according to the eleventh embodiment of the present disclosure.

FIG. 18 is a schematic top view diagram illustrating an electronic device according to a twelfth embodiment of the present disclosure.

FIG. 19 is a schematic diagram illustrating cross-sectional structures of electronic devices according to some embodiments of the present disclosure.

### DETAILED DESCRIPTION

The contents of the present disclosure will be described in detail with reference to specific embodiments and drawings. It is noted that, for purposes of illustrative clarity and being easily understood by the readers, the following drawings may be simplified schematic diagrams, and components therein may not be drawn to scale. The components and combinations thereof related to the present disclosure are shown to provide a clear description of the basic structure or implementation of the present disclosure, however, the actual components and layout may be more complicated. Additionally, the numbers, shapes and dimensions of the components in the drawings are just illustrative, and are not intended to limit the scope of the present disclosure. The detailed scales of components can be adjusted according to the designs.

Certain terms are used throughout the description and following claims to refer to particular components. As one skilled in the art will understand, electronic equipment manufacturers may refer to a component by different names. This disclosure does not intend to distinguish between components that differ in name but not function. In the following description and in the claims, the terms “include” and “comprise” are used in an open-ended fashion, and thus should be interpreted to mean “include, but not limited to . . . ”.

The directional terms mentioned in this disclosure, such as “up”, “down”, “front”, “back”, “left”, “right”, etc., are only directions referring to the drawings. Therefore, the directional terms are used for illustration, not to limit the present disclosure. In the drawings, each drawing shows the general characteristics of methods, structures and/or materials used in specific embodiments. However, these drawings should not be construed as defining or limiting the scope or nature covered by these embodiments. For example, the relative size, thickness and position of each layer, region and/or structure may be reduced or enlarged for clarity.

It should be understood that when a component or layer is referred to as being “on”, “disposed on” or “connected to” another component or layer, it may be directly on or directly connected to the other component or layer, or intervening components or layers may be presented (indirect condition). In contrast, when a component is referred to as being “directly on”, “directly disposed on” or “directly connected to” another component or layer, there are no intervening components or layers presented. In addition, the arrangement relationship between different components may be interpreted according to the contents of the drawings.

The terms “about”, “equal”, “identical” or “the same”, and “substantially” or “approximately” mentioned in this document generally mean being within 20% of a given value or range, or being within 10%, 5%, 3%, 28, 1% or 0.5% of a given value or range.

The electrical connection can be direct electrical connection or indirect electrical connection. The electrical connection between two components can be achieved by direct contact in order to transmit electrical signals, and there may be no other components between them. The electrical connection between two components can also be bridged by the component between them in order to transmit electrical signals. Electrical connection can also be called coupling.

In addition, it should be understood that although the terms “first”, “second”, “third”, etc. may be used herein to describe various components, these components should not be limited by these terms. These terms may be used to distinguish different components in the specification. The same terms may not be used in the claims, and the components in the claims may be described by the terms “first”, “second”, “third”, etc. according to the order of the components presented in the claims. Thus, a first component discussed below may be termed as a second component in the claims.

It should be understood that according to the following embodiments, features of different embodiments may be replaced, recombined or mixed to constitute other embodiments without departing from the spirit of the present disclosure.

The comparison of thicknesses, areas and widths between different components in the following text can be conducted by optical microscope (OM), scanning electron microscope (SEM) and other suitable instruments, and the comparison can be conducted in the same photo or more than one photo.

The electronic device of the present disclosure may include, for example, a display device, a backlight device, an antenna device, a sensing device or a tiled device, but not limited thereto. The electronic device may be bendable, flexible or rollable electronic device. The display device may include a non-self-emissive display device or a self-emissive display device, but not limited thereto. The display device may include, for example, liquid crystal, light-emitting diodes (LED), fluorescence material, phosphorescence material, quantum dots (QD), other suitable display medium, or combinations thereof, but not limited thereto. The antenna device may include, for example, a liquid crystal antenna or other kinds of antenna, but not limited thereto. The sensing device may be used for detecting capacitance change, light, thermal energy or ultrasonic waves for example, but not limited thereto.

The electronic device may include electronic units, the electronic units may include passive components or active components, such as capacitors, resistors, inductors, diodes, etc. The diodes may include, for example, light emitting diodes or photodiodes, but not limited thereto. The light emitting diodes may include, for example, organic light emitting diodes (OLED), mini light emitting diodes (mini-LED), micro light emitting diodes (micro-LED) or quantum dots (QD) light emitting diodes, but not limited thereto. The tiled device may include, for example, a tiled display device of a tiled antenna device, but not limited thereto.

It should be noted that the electronic device of the present disclosure may be any combination of the aforementioned devices, but not limited thereto. In addition, the appearance of the electronic device may be rectangular, circular, polygonal, a shape with curved edges, or other suitable shapes. The electronic device may have peripheral systems such as a driving system, a control system, a light source system, a shelf system, etc., to support a display device, an antenna device, a wearable device (such as augmented reality or virtual reality device), a vehicle-mounted device (such as windshields), or a tiled device.

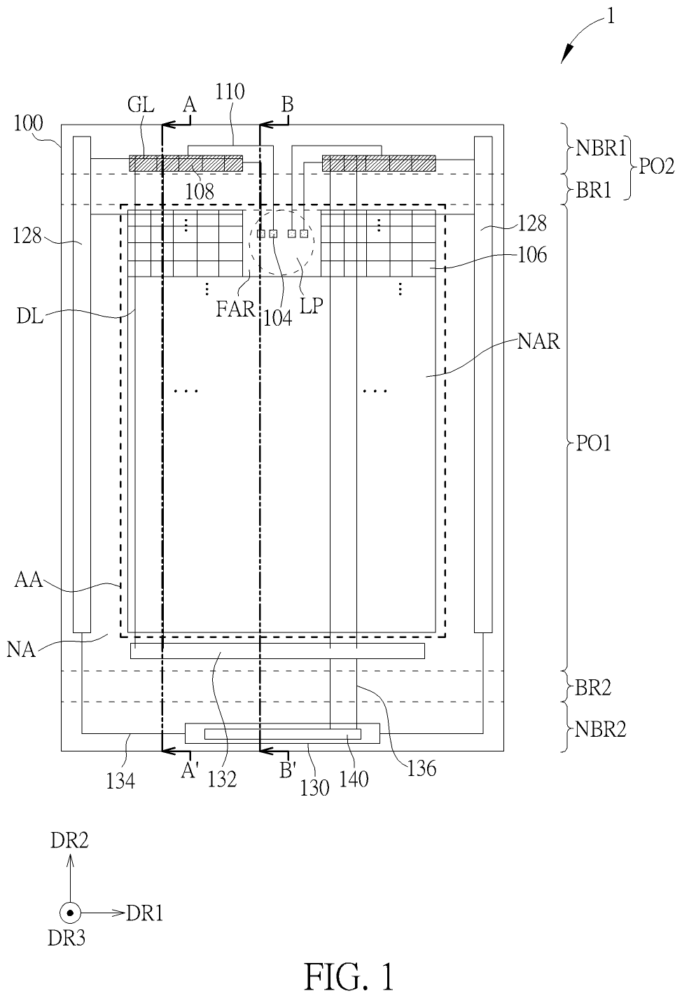

A direction DR1, a direction DR2 and a direction DR3 are shown in the following drawings. The direction DR3 may be a normal direction or a top view direction, as shown in FIG. 1, the direction DR3 may be perpendicular to a surface (such as a top surface or a bottom surface) of a substrate 100. The direction DR1 and the direction DR2 may be horizontal directions and perpendicular to the direction DR3. As shown in FIG. 1, the direction DR1 and the direction DR2 may be parallel to the surface of the substrate 100, and the direction DR1 may be perpendicular to the direction DR2. The spatial relationship of the structure may be described according to the direction DR1, the direction DR2 and the direction DR3 in the following drawings.

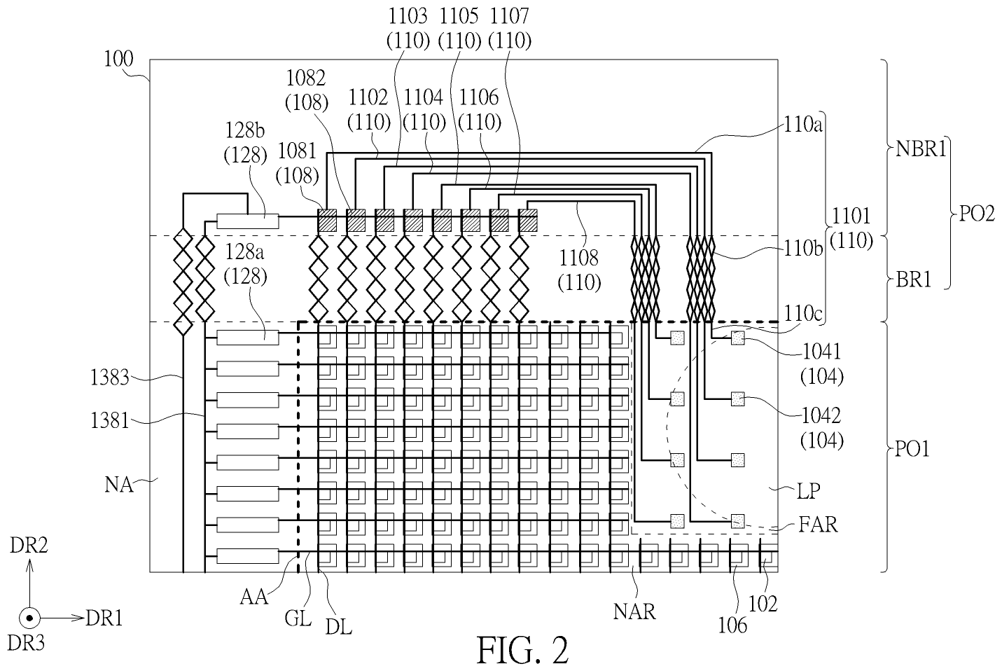

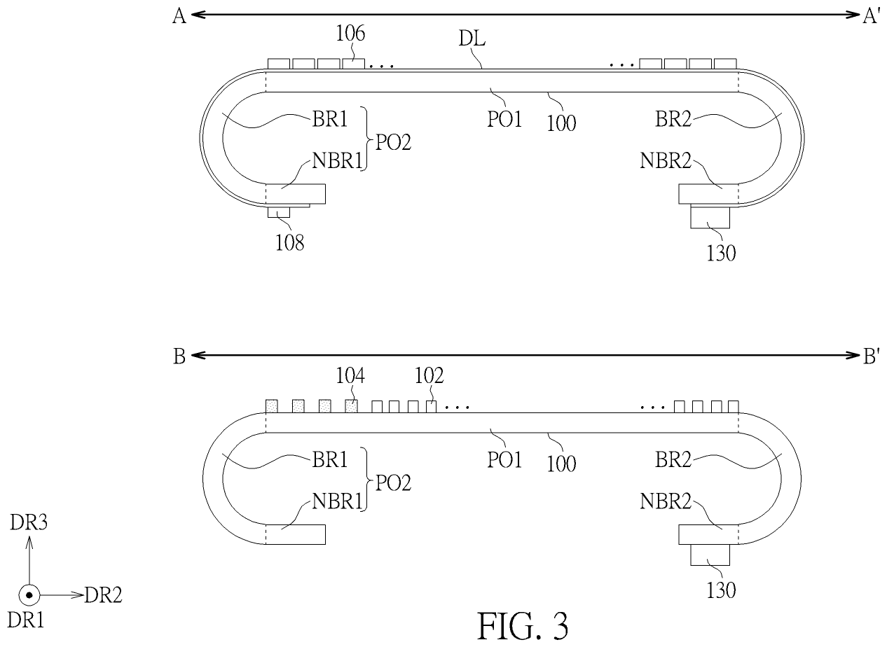

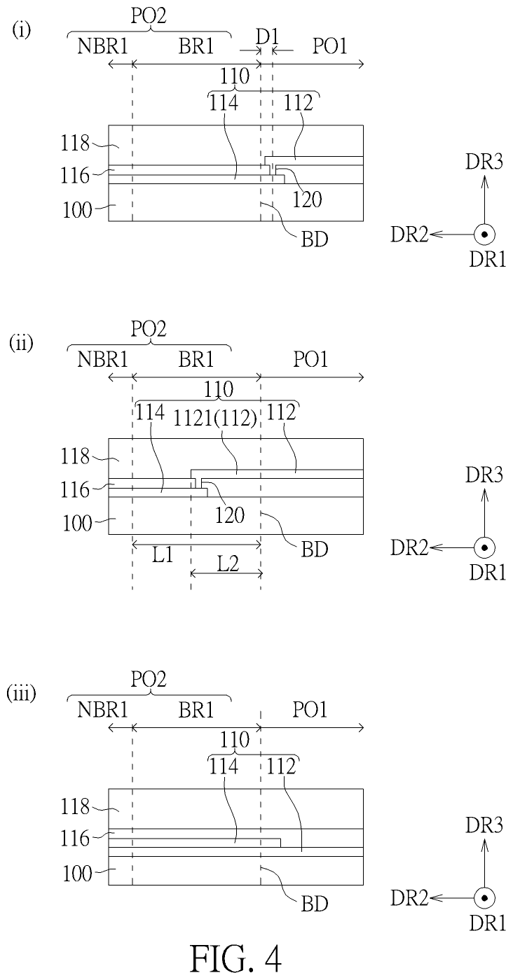

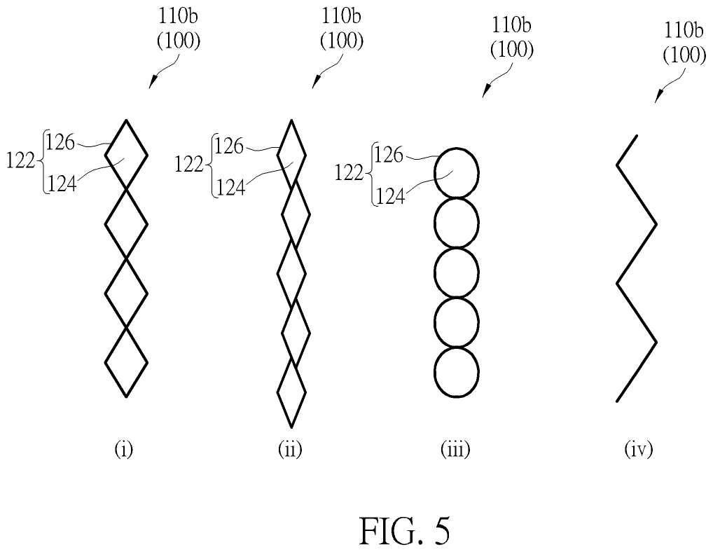

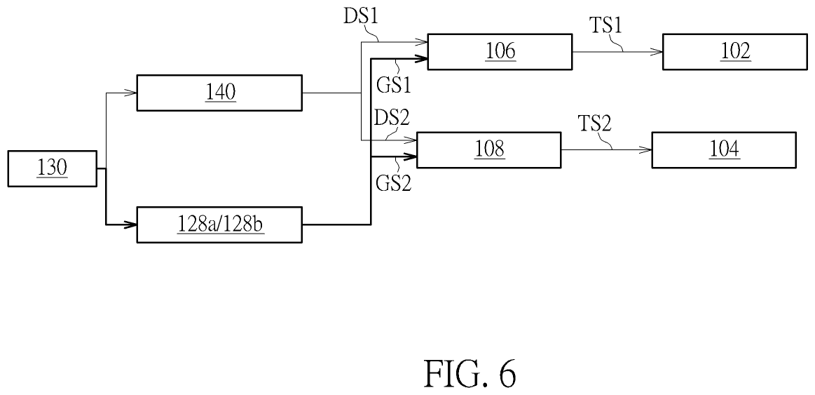

Please refer to FIG. 1 to FIG. 6. FIG. 1 is a schematic top view diagram illustrating an electronic device according to a first embodiment of the present disclosure. FIG. 2 is a partially enlarged top view diagram illustrating the electronic device according to the first embodiment of the present disclosure. FIG. 3 is a schematic cross-sectional diagram illustrating the electronic device according to the first embodiment of the present disclosure along a line A-A′ and a line B-B′ in FIG. 1. FIG. 4 is a schematic diagram illustrating cross-sectional structures of a portion of a connection line according to some embodiments of the present disclosure. FIG. 5 is a schematic diagram illustrating anti-crack patterns of a connection line according to some embodiments of the present disclosure. FIG. 6 is a block diagram of signal processing of the electronic device according to the first embodiment of the present disclosure. In some embodiments, the electronic device can be a display device, but not limited thereto. In the following embodiments, the display device will be used as an example for explaining the technical features of the electronic device.

In order to highlight the technical features of the present disclosure, the following drawings only show one substrate and the components on the substrate in the electronic device, but the electronic device may also include other substrates. In some embodiments, the substrate may be the array substrate of the display device, but not limited thereto. In addition, FIG. 1 and FIG. 2 show an unbent substrate, and FIG. 3 shows a bent substrate. Furthermore, FIG. 2 may be an enlarged schematic view of the upper left part of the substrate in FIG. 1.

As shown in FIG. 1, the electronic device 1 may include a substrate 100, the substrate 100 may include a deformable substrate, and the deformable substrate may be flexed, curved, bent, stretched or deformed in any other way, but not limited thereto. The material of the substrate 100 may include polyimide (PI), polycarbonate (PC), polyethylene terephthalate (PET), other suitable materials, or combinations of the above materials, but not limited thereto.

The substrate 100 may include an active region AA and a peripheral region NA disposed on at least one side of the active region AA. As shown in FIG. 1, in some embodiments, the peripheral region NA may surround the active region AA, but not limited thereto. In some embodiments, the active region AA may be a display region of the display device, but not limited thereto.

The electronic device 1 may include a plurality of electronic units (such as light emitting units or sub-pixels, but not limited thereto) and a portion of working circuits (such as pixel circuits, but not limited thereto) disposed on the active region AA of the substrate 100, and the electronic device 1 may include driving circuits, chips, demultiplexers (DEMUX) and another portion of working circuits disposed on the peripheral region NA of the substrate 100, but not limited thereto.

In another aspect, the substrate 100 may include a first portion PO1 and a second portion PO2 bent with respect to the first portion PO1 (the bent substrate 100 is shown FIG. 3). As shown in FIG. 1, the second portion PO2 may be disposed above the first portion PO1 in the direction DR2. The first portion PO1 may include the active region AA and a portion of the peripheral region NA located on the left and right sides of the active region AA, and the second portion PO2 may include a portion of the peripheral region NA located above the active region AA.

The first portion PO1 and the active region AA in the first portion PO1 may have a normal active region NAR and a functional active region FAR. The normal active region NAR may have a notch, and the functional active region FAR may be disposed in the notch. The functional active region FAR may have a light-transmitting portion LP. In some embodiments, the camera may be disposed corresponding to the light-transmitting portion LP, thus the camera can receive light. The normal active region NAR and the functional active region FAR can form the active region AA, but not limited to thereto.

As shown in FIG. 1, the second portion PO2 may have a bending region BR1 and a first region NBR1. The bending region BR1 may be disposed between the first region NBR1 and the first portion PO1 (including the normal active region NAR and the functional active region FAR) in the direction DR2. As shown in FIG. 3, the second portion PO2 can be bent with respect to the first portion PO1 through the bending region BR1. In some embodiments, the first region NBR1 may be located at the back side of the first portion PO1 after the bending region BR1 is bent. Therefore, a portion of the second portion PO2 (such as the first region NBR1) can be overlapped with the first portion PO1 in a normal direction (such as the direction DR3) of a surface of the first portion PO1. In this way, the width of the border can be further reduced to achieve narrow border design or borderless design. In addition, the proportion of the screen of the electronic device can also be increased to realize full-screen electronic technology.

In addition, the substrate 100 may further have a bending region BR2 and a second region NBR2. As shown in FIG. 1, in the direction DR2, the first portion PO1 may be disposed between the bending region BR1 and the bending region BR2, and the bending region BR2 may be disposed between the first portion PO1 and the second region NBR2. As shown in FIG. 3, the second region NBR2 may be located at the back side of the first portion PO1 after the bending region BR2 is bent. Therefore, the width of the border can be further reduced to achieve the narrow border design or borderless design. The first portion PO1, the first region NBR1 and the second region NBR2 may be regions without bending (or flat regions), but not limited thereto.

As shown in FIG. 2, the electronic device 1 may include a plurality of main electronic units 102 and a plurality of auxiliary electronic units 104. The main electronic units 102 may be disposed on the normal active region NAR of the substrate 100, and the auxiliary electronic units 104 may be disposed on the functional active region FAR of the substrate 100. In some embodiments, the main electronic units 102 and the auxiliary electronic units 104 may for example be light emitting units, but not limited thereto. In some embodiments, the main electronic units 102 and the auxiliary electronic units 104 may for example be sub-pixels, but not limited thereto.

As shown in FIG. 1 and FIG. 2, the electronic device 1 may include a plurality of main working circuits 106 and a plurality of auxiliary working circuits 108. In some embodiments, the main working circuits 106 and the auxiliary working circuits 108 may for example be pixel circuits, but not limited thereto. The pixel circuits may include thin film transistors, capacitors or other electronic components, but not limited thereto. In some embodiments, the thin film transistors of the main working circuits 106 and the auxiliary working circuits 108 may include low-temperature polycrystalline silicon, metal oxide or a combination of the above, but not limited thereto. For example, the main working circuits 106 and the auxiliary working circuits 108 respectively may include low-temperature polycrystalline silicon transistors and metal oxide transistors, but not limited thereto.

The main working circuits 106 may be disposed on the first portion PO1 of the substrate 100. Specifically, the main working circuits 106 may be disposed on the normal active region NAR of the first portion PO1. The main working circuits 106 may be correspondingly disposed below the main electronic units 102 in the direction DR3. The main working circuits 106 and the main electronic units 102 may be arranged into a plurality of main working circuit rows and a plurality of main electronic unit rows in the normal active region NAR, and the main working circuit rows and the main electronic unit rows can extend along the direction DR1, but not limited to thereto.

The auxiliary working circuits 108 may be disposed on the second portion PO2 of the substrate 100. In some embodiments, as shown in FIG. 2, the auxiliary working circuits 108 may be disposed on the first region NBR1 of the second portion PO2, and the auxiliary working circuits 108 may be arranged into at least one auxiliary working circuit row in a region of the first region NBR1 near the bending region BR1.

When the auxiliary working circuits 108 are disposed on the second portion PO2 of the substrate 100, the area of the light-transmitting portion LP of the functional active region FAR can be increased because the light passing through the light-transmitting portion LP of the functional active region FAR may not be blocked by the auxiliary working circuits 108, and the imaging effect of the camera can be further improved.

In some embodiments, the auxiliary working circuits 108 may include a plurality of thin film transistors. A portion of the thin film transistors may be disposed on the first region NBR1 of the second portion PO2. The other portion of the thin film transistors may be disposed on the functional active region FAR of the first portion PO1 of the substrate 100, and this portion of the thin film transistors may be correspondingly disposed below the auxiliary electronic units 104 in the direction DR3.

One main working circuit 106 can be electrically connected to one main electronic unit 102, and one auxiliary working circuit 108 can be electrically connected to one auxiliary electronic unit 104, but not limited thereto. In some embodiments, the electronic device 1 may be a light emitting diode display device, the main electronic units 102 and the auxiliary electronic units 104 may be defined by using light emitting diodes as the light emitting units, and the main working circuits 106 and the auxiliary working circuits 108 may be electrically connected to the light emitting diodes, but not limited thereto. In some embodiments, the electronic device 1 may be a liquid crystal display device, the main electronic units 102 and the auxiliary electronic units 104 may be defined by using pixel electrodes as the light emitting units, and the main working circuits 106 and the auxiliary working circuits 108 may be electrically connected to the pixel electrodes, but not limited thereto.

In the present disclosure, the auxiliary electronic units 104 can be disposed on the functional active region FAR of the first portion PO1 of the substrate 100, and at least a portion of the auxiliary working circuits 108 can be disposed on the second portion PO2 of the substrate 100. Additionally, the electronic device 1 can include a plurality of connection lines 110 disposed on the substrate 100, and the auxiliary working circuits 108 can be electrically connected to the auxiliary electronic units 104 through the connection lines 110.

In some embodiments, a part of the connection line 110 may be disposed on the first portion PO1 of the substrate 100, and another part of the connection line 110 may be disposed on the second portion PO2 of the substrate 100. As shown in FIG. 2, the connection line 110 may include a part 110a, a part 110b and a part 110c, but not limited thereto. The part 110a may be disposed on the first region NBR1 of the second portion PO2, and one end of the part 110a may be connected to the auxiliary working circuit 108. The part 110b may be disposed on the bending region BR1 of the second portion PO2, one end of the part 110b may be connected to the part 110a, and another end of the part 110b may be connected to the part 110c. The part 110c may be disposed on the first portion PO1 and on the functional active region FAR, and one end of the part 110c may be connected to the auxiliary electronic unit 104.

The connection lines 110 may include one or more conductive layers, and the material of the connection lines 110 may include a metal material, a transparent conducting oxide (TCO) or a combination of the above materials, but not limited thereto. In some embodiments, the connection lines 110 may include or may be formed of the same conductive layer, but not limited thereto.

In other embodiments, any two adjacent connection lines 110 may include or be formed of different conductive layers. As shown in FIG. 2, an auxiliary working circuit 1081 may be electrically connected to an auxiliary electronic unit 1041 through a connection line 1101, and an auxiliary working circuit 1082 may be electrically connected to an auxiliary electronic unit 1042 through a connection line 1102, the connection line 1101 and the connection line 1102 are adjacent to each other and may include or be formed of different layers.

For example, the connection line 1101, a connection line 1103, a connection line 1105 and a connection line 1107 may be formed of one or more of the same conductive layers, and the connection line 1102, a connection line 1104, a connection line 1106 and a connection line 1108 may be formed of one or more of the same conductive layers. However, the conductive layers of the connection line 1101, the connection line 1103, the connection line 1105 and the connection line 1107 may be different from the conductive layers of the connection line 1102, the connection line 1104, the connection line 1106 and the connection line 1108.

Therefore, the distance between adjacent connection lines 110 can be further reduced, the width of the border can be further reduced, and the excessive parasitic capacitance caused by the close distance of adjacent connection lines can also be reduced.

In addition, the resistances of the connection lines 110 may be inconsistent when different connection lines 110 have different lengths. Therefore, in some embodiments, the line width of the connection line 1101 with the longest length may be greater than the line width of the connection line 1108 with the shortest length, and the resistance difference between the connection lines 110 with different lengths may be less than 2%, thereby making the quality of signal transmission more consistent.

In some embodiments, the connection lines 110 may be formed by connecting a plurality of different conductive layers. As shown in example (i) in FIG. 4, the connection line 110 may include a first layer 112 and a second layer 114. The first layer 112 may be at least disposed on the first portion PO1, and the second layer 114 may be at least disposed on the second portion PO2. One end of the first layer 112 can be connected to the auxiliary electronic unit 104, and one end of the second layer 114 can be connected to the auxiliary working circuit 108, but not limited thereto. The first layer 112 may include the transparent conductive material, and the second layer 114 may include the metal material, but not limited thereto.

Since the first layer 112 may be disposed on the functional active region FAR or the light-transmitting portion LP of the functional active region FAR in the first portion PO1 in FIG. 2, the chance of light that passes through this region being blocked by materials can be reduced when the first layer 112 includes the transparent conductive material, thereby improving the imaging effect of the camera. In addition, the resistance of the connection line 110 can be reduced when the second layer 114 disposed on the second portion PO2 includes the metal material, and the connection line 110 may also have better ductility.

As shown in example (i) in FIG. 4, the second layer 114 may be disposed between the substrate 100 and the first layer 112, an insulating layer 116 may be disposed between the first layer 112 and the second layer 114, an insulating layer 118 may be disposed on the first layer 112, and the first layer 112 may be filled in a contact hole 120 in the insulating layer 116 to connect with the second layer 114. The insulating layer 116 and the insulating layer 118 may include organic insulating materials or inorganic insulating materials, but not limited thereto. However, the cross-sectional structure of the electronic device 1 is not limited to the content of FIG. 4, and the electronic device 1 may have a more complicated structure.

In some embodiments, the first layer 112 is connected to the second layer 114 at a position (such as the position of the contact hole 120) near a boundary BD between the first portion PO1 and the second portion PO2. As shown in example (i) in FIG. 4, the contact hole 120 may be located in the first portion PO1 and close to the boundary BD, but not limited thereto. The boundary BD may be a position where the substrate 100 starts to bent from a flat region. If a supporting film is disposed under the substrate 100, the boundary BD may be a position where the substrate 100 overlaps the edge of the supporting film. A distance D1 between the boundary BD and the contact hole 120 may be greater than zero and less than or equal to 100 micrometers. The distance D1 can be calculated from the center of the contact hole 120 to the boundary BD, but not limited thereto.

In some embodiments, as shown in example (ii) in FIG. 4, the bending region BR1 of the second portion PO2 has a first length L1, the first layer 112 may have a portion 1121 disposed on the bending region BR1, and the portion 1121 of the first layer 112 has a second length L2. The ratio of the second length L2 to the first length L1 may be less than or equal to 0.5, but not limited thereto. When the first layer 112 includes the transparent conductive material, it might be easier to break the first layer 112 during bending since the transparent conductive material is brittle. However, the chance of breaking the first layer 112 of the connection line 110 can be reduced when the ratio of the second length L2 to the first length L1 is less than or equal to 0.5.

In some embodiments, as shown in example (iii) in FIG. 4, the first layer 112 may be disposed on the first portion PO1 and the second portion PO2 of the substrate 100, and the second layer 114 may be disposed on the second portion PO2 and a portion of the first portion PO1 of the substrate 100. One end of the first layer 112 and/or one end of the second layer 114 can be connected to the auxiliary working circuit 108, and the other end of the first layer 112 can be connected to the auxiliary electronic unit 104. The second layer 114 may only extend into a portion of the first portion PO1, and the second layer 114 may not extend into the functional active region FAR or the light-transmitting portion LP of the functional active region FAR in the first portion PO1, thus the chance of light that passes through this region being blocked by materials may be reduced.

In addition, in some embodiments, the first layer 112 and the second layer 114 may be disposed between the substrate 100 and the insulating layer 116, and the second layer 114 may be disposed on the first layer 112 and may directly contact with the first layer 112 to reduce the resistance of the connection line 110.

Please refer to FIG. 2 again, the part 110b of the connection line 110 disposed on the bending region BR1 of the second portion PO2 may include an anti-crack pattern to reduce the probability of breaking the part 110b of the connection line 110 after bending. In some embodiments, a portion of the part 110a of the connection line 110 may also include the anti-crack pattern, and the portion of the part 110a may be adjacent to the part 110b. In some embodiments, a portion of the part 110c of the connection line 110 may also include the anti-crack pattern, and the portion of the part 110c may be adjacent to the part 110b.

In some embodiments, as shown in example (i) in FIG. 5, the anti-crack pattern of the connection line 110 may include a plurality of anti-crack units 122 connected to each other, the shape of the anti-crack unit 122 may for example be a rhombus, and one corner of one anti-crack unit 122 may be connected to one corner of an adjacent anti-crack unit 122 to form a chain structure, but not limited thereto. The anti-crack unit 122 may include an opening 124 and a conductive wire 126 surrounding the opening 124, and the material of the conductive wire 126 may be the same as the material of the connection line 110, and it is not redundantly described herein.

In some embodiments, as shown in example (ii) in FIG. 5, the difference between example (ii) and example (i) is that a portion of a side of one anti-crack unit 122 can be connected with a portion of a side of an adjacent anti-crack unit 122. In some embodiments, as shown in example (iii) in FIG. 5, the difference between example (iii) and example (i) is that the shape of the anti-crack unit 122 may for example be a circle, but not limited thereto. In some embodiments, as shown in example (iv) in FIG. 5, the anti-crack pattern of the part 110b of the connection line 110 may include a zigzag line, but not limited thereto.

Please refer to FIG. 1 again, the electronic device 1 may include a plurality of gate lines GL, a plurality of data lines DL, a plurality of gate driving circuits 128, a chip 130 and a demultiplexer 132 disposed on the substrate 100, but not limited thereto. The data lines DL may be extended in the direction DR2, and the gate lines GL may be extended in the direction DR1. The main working circuit 106 can be electrically connected to one of the gate lines GL and one of the data lines DL, and the auxiliary working circuit 108 can also be electrically connected to one of the gate lines GL and one of the data lines DL.

The gate driving circuits 128 may be disposed on the peripheral region NA of the substrate 100, one of the gate driving circuits 128 may be disposed on the left side of the normal active region NAR, and the other one of the gate driving circuits 128 may be disposed on the right side of the normal active region NAR, but not limited thereto. The gate driving circuits 128 may be electrically connected to the gate lines GL, and the gate driving circuits 128 may be electrically connected to the chip 130 through at least one signal line 134.

The gate driving circuits 128 in FIG. 1 may include a plurality of main gate drivers 128a and at least one auxiliary gate driver 128b in FIG. 2. The main gate drivers 128a may be disposed on the first portion PO1 of the substrate 100, and the auxiliary gate driver 128b may be disposed on the second portion PO2 of the substrate 100. As shown in FIG. 2, the auxiliary gate driver 128b may be disposed on the first region NBR1 of the second portion PO2 of the substrate 100, but not limited thereto.

In addition, the gate driver may include thin film transistors, capacitors or other electronic components, but not limited thereto. In some embodiments, the gate driver may include at least one low temperature polycrystalline silicon (LTPS) thin film transistor, at least one metal oxide thin film transistor or a combination thereof, but not limited thereto.

One main gate driver 128a can be electrically connected to one gate line GL, and the main gate driver 128a can be electrically connected to the corresponding main working circuit 106 through the gate line GL, thus the main gate driver 128a can transmit signals to the main working circuit 106. One auxiliary gate driver 128b can be electrically connected to another gate line GL, and the auxiliary gate driver 128b can be electrically connected to the corresponding auxiliary working circuit 108 through the gate line GL, thus the auxiliary gate driver 128b can transmit signals to the auxiliary working circuit 108. As shown in FIG. 2, the number of the auxiliary working circuits 108 electrically connected to one auxiliary gate driver 128b may be less than the number of the main working circuits 106 electrically connected to one main gate driver 128a.

The signal output by the gate driver may have different RC loadings when the number of working circuits electrically connected to the gate driver is different. In some embodiments, the auxiliary gate driver 128b may have an auxiliary output thin film transistor, the main gate driver 128a may have a main output thin film transistor, and the ratio of the channel width to the channel length of the auxiliary output thin film transistor may be less than the ratio of the channel width to the channel length of the main output thin film transistor. Therefore, the driving power of the main gate driver 128a and the auxiliary gate driver 128b can match their corresponding RC loadings, thereby making the signal transmission quality more consistent.

For example, the auxiliary output thin film transistor and the main output thin film transistor respectively may be the thin film transistors located closest to the gate lines GL in the auxiliary gate driver 128b and the main gate driver 128a. In addition, in the main output thin film transistor and the auxiliary output thin film transistor, a portion of the channel layer may be overlapped with the gate, and the channel length can be obtained by measuring the portion of the channel layer in a direction from the source to the drain, and the channel width can be obtained by measuring the portion of the channel layer in another direction that is perpendicular to the above direction.

As shown in FIG. 1, the chip 130 can be electrically connected to the main working circuits 106 and the auxiliary working circuits 108 through signal lines 136, the demultiplexer 132 and the data lines DL, and a source driver 140 in the chip 130 can transmit signals to the main working circuits 106 and the auxiliary working circuits 108. The demultiplexer 132 and the chip 130 may be disposed on the peripheral region NA of the substrate 100. The demultiplexer 132 may be disposed on the first portion PO1 and below the normal active region NAR of the substrate 100. The demultiplexer 132 may include a plurality of thin film transistors, and the demultiplexer 132 may be electrically connected to the signal lines 136 and the data lines DL, but not limited thereto. The chip 130 is disposed on the second region NBR2 of the substrate 100, but not limited thereto. As shown in FIG. 3, the chip 130 and the second region NBR2 of the substrate 100 may be bent to the back side of the first portion PO1 of the substrate 100, but not limited thereto.

As shown in FIG. 2, the electronic device 1 may include a signal line 1381 and a signal line 1383 disposed on the peripheral region NA of the substrate 100. The signal line 1381 and the signal line 1383 may be disposed between the main gate drivers 128a and the edge of the substrate 100 and also between the auxiliary gate driver 128b and the edge of the substrate 100 in the direction DR1, but not limited thereto. The signal line 1381 may be a clock signal line for example, and the signal line 1381 may be electrically connected to the main gate drivers 128a and the auxiliary gate driver 128b, but not limited thereto. The signal line 1383 may be a start signal line for example, and the signal line 1383 may be electrically connected to the auxiliary gate driver 128b, but not limited thereto. In addition, the signal line 1381 and the signal line 1383 may be electrically connected to the chip 130, but not limited thereto.

The gate lines GL, the data lines DL, the signal lines 134, the signal lines 136, the signal line 1381 and the signal line 1383 may include conductive materials such as metals, but not limited thereto. In some embodiments, as shown in FIG. 2, a portion of the data line DL, a portion of the signal line 1381 and a portion of the signal line 1383 disposed on the bending region BR1 may include the above-mentioned anti-crack patterns, but not limited thereto.

As shown in FIG. 6, in some embodiments, the source driver 140 can be controlled by the chip 130 to output a signal DS1 and a signal DS2, and the main gate driver 128a and the auxiliary gate driver 128b can be controlled by the chip 130 to output a signal GS1 and a signal GS2. The source driver 140 may transmit the signal DS1 to the main working circuit 106 and transmit the signal DS2 to the auxiliary working circuit 108 through the data lines DL, but not limited thereto. The main gate driver 128a may transmit the signal GS1 to the main working circuit 106 through the corresponding gate line GL, and the auxiliary gate driver 128b may transmit the signal GS2 to the auxiliary working circuits 108 through the corresponding gate line GL, but not limited thereto.

The main working circuit 106 is configured to receive a first data signal (such as the signal DS1, the signal GS1 or a combination of both) and output a first driving signal TS1 to the main electronic unit 102 according to the first data signal. The auxiliary working circuit 108 is configured to receive a second data signal (such as the signal DS2, the signal GS2 or a combination of both) and output a second driving signal TS2 to the auxiliary electronic unit 104 according to the second data signal.

In some embodiments, when the main working circuit 106 and the auxiliary working circuit 108 are pixel circuits, the main working circuit 106 and the auxiliary working circuit 108 can receive the first data signal and the second data signal through the data lines DL, and the main working circuit 106 and the auxiliary working circuit 108 can output the first driving signal TS1 (such as a first current) and the second driving signal TS2 (such as a second current) according to the first data signal and the second data signal. When the main electronic unit 102 and the auxiliary electronic unit 104 are organic light emitting diodes, the main electronic unit 102 and the auxiliary electronic unit 104 can receive the first driving signal TS1 and the second driving signal TS2 through the anodes of the organic light emitting diodes, but not limited thereto.

Subsequent paragraphs will continue to detail other embodiments of the present disclosure. For simplicity, identical elements will be denoted by the same reference signs. To illustrate the differences between various embodiments, the following paragraphs will describe in more detail the differences between various embodiments while omitting descriptions regarding previously discussed features.

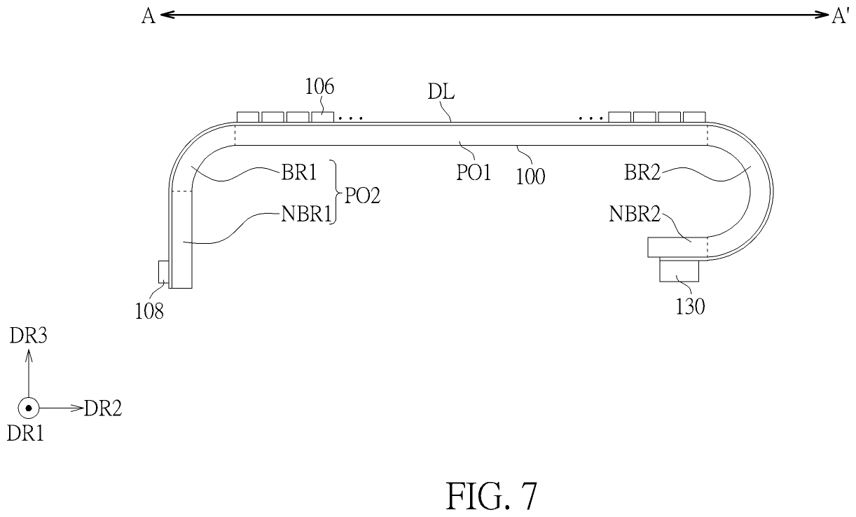

Please refer to FIG. 7, FIG. 7 is a schematic cross-sectional diagram illustrating an electronic device according to a second embodiment of the present disclosure along a line A-A′ in FIG. 1. In some embodiments, the first region NBR1 may be located at one side of the first portion PO1 in the direction DR2 after the bending region BR1 is bent. Therefore, the second portion PO2 is not overlapped with the first portion PO1 in the normal direction (such as the direction DR3) of a surface of the first part PO1. In this way, the width of the border can be further reduced to achieve narrow border design or borderless design. In addition, the chance of light that passes through the functional active region FAR (or passes through the light-transmitting portion LP) in the first portion PO1 being blocked by elements on the second portion PO2 can be reduced, and the imaging effect of the camera can be further improved.

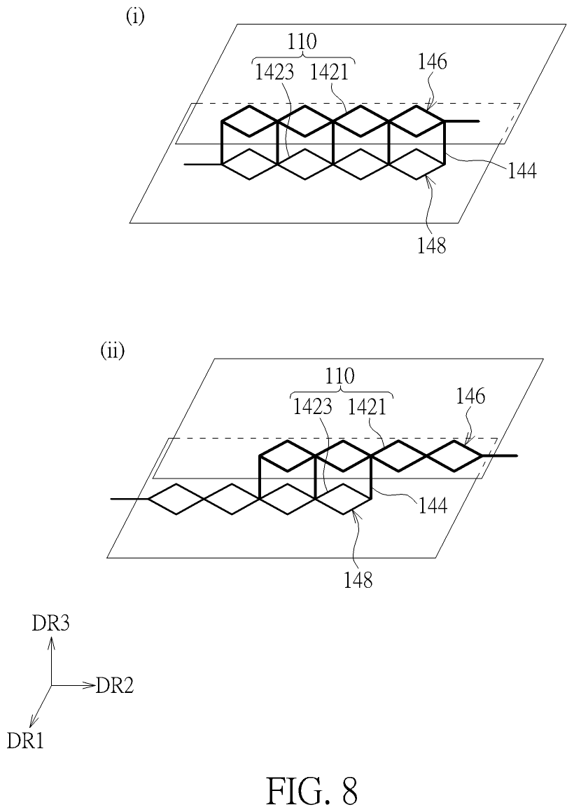

Please refer to FIG. 8, FIG. 8 is a schematic diagram illustrating anti-crack patterns of a connection line according to a third embodiment of the present disclosure. In some embodiments, the connection lines 110 may be formed by connecting a plurality of conductive layers having anti-crack patterns, and the conductive layers may include metal materials, transparent conductive materials or combinations thereof, but not limited thereto. As shown in example (i) in FIG. 8, the connection line 110 may include a first layer 1421 and a second layer 1423, the first layer 1421 and the second layer 1423 may be disposed on two different planes in the electronic device 1, and the first layer 1421 may be disposed on the second layer 1423. For example, the first layer 1421 may be one of the metal material and the transparent conductive material, and the second layer 1423 may be the other one of the metal material and the transparent conductive material, but not limited thereto.

In addition, an insulating layer can be disposed between the first layer 1421 and the second layer 1423. A portion of the first layer 1421 can be filled into contact holes in the insulating layer to form a plurality of contacts 144, and the first layer 1421 and the second layer 1423 can be electrically connected with each other through the contacts 144.

The first layer 1421 and the second layer 1423 may include the anti-crack patterns, and the anti-crack patterns may include the anti-crack units connected with each other, and the definition of the anti-crack unit may refer to the relevant paragraphs of FIG. 5. The anti-crack pattern of the first layer 1421 may include a plurality of anti-crack units 146 connected with each other, the anti-crack pattern of the second layer 1423 may include a plurality of anti-crack units 148 connected with each other, and the shape of the anti-crack units 146 and the anti-crack units 148 may be rhombus for example, but not limited thereto. A corner of the anti-crack unit 146 can be connected with a corner of the adjacent anti-crack unit 146. A corner of the anti-crack unit 148 can be connected with a corner of the adjacent anti-crack unit 148. The contacts 144 can be disposed at the positions where adjacent anti-crack units 146 are connected with each other and at the positions where adjacent anti-crack units 148 are connected with each other.

In some embodiments, as shown in example (i) in FIG. 8, each of the anti-crack units 146 may be overlapped with the corresponding anti-crack unit 148 in the direction DR3, but not limited thereto. In some embodiments, as shown in example (ii) in FIG. 8, in the direction DR3, a portion of the anti-crack units 146 may be overlapped with a corresponding portion of the anti-crack units 148, the remaining portion of the anti-crack units 146 may not overlap with the anti-crack units 148, and the remaining portion of anti-crack units 148 may not overlap with the anti-crack units 146, but not limited thereto.

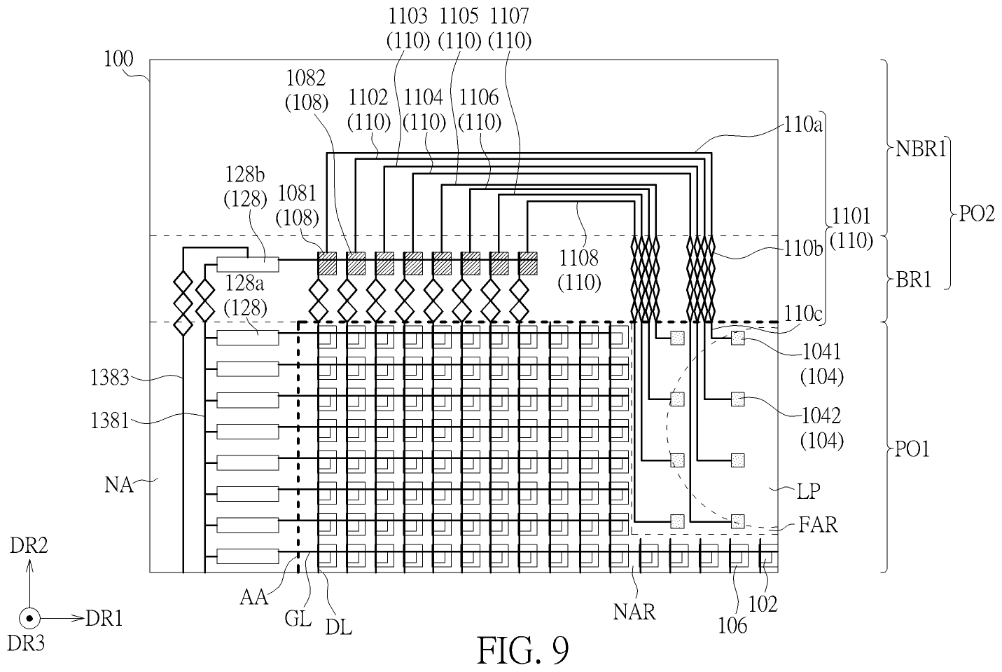

Please refer to FIG. 9, FIG. 9 is a partially enlarged top view diagram illustrating an electronic device according to a fourth embodiment of the present disclosure. Different from the first embodiment, the auxiliary working circuits 108, the auxiliary gate driver 128b and the gate line GL electrically connecting the auxiliary working circuits 108 and the auxiliary gate driver 128b of this embodiment can be disposed on the bending region BR1 of the second portion PO2, but not limited thereto.

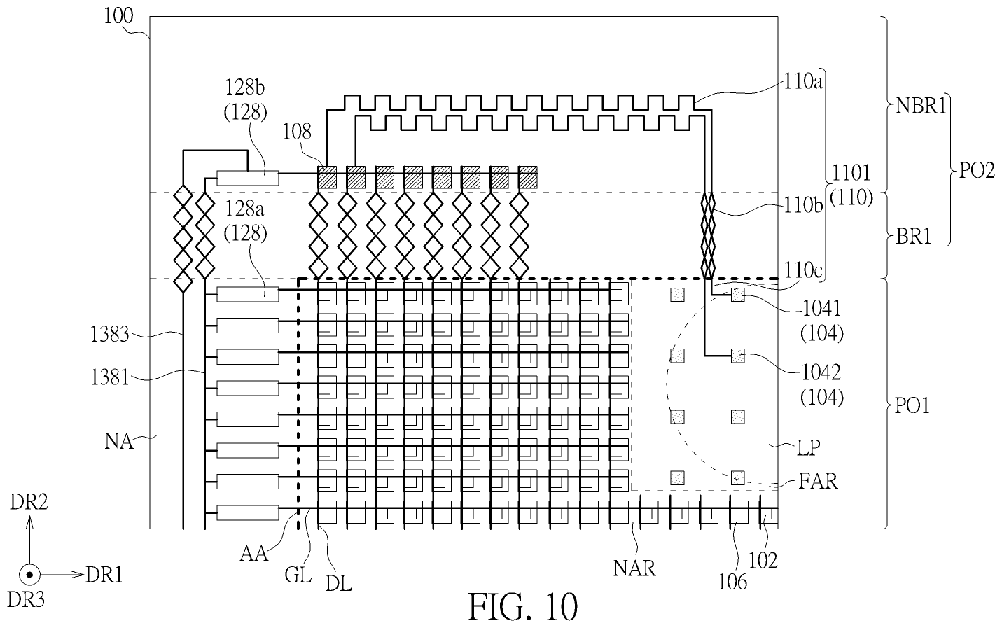

Please refer to FIG. 10, FIG. 10 is a partially enlarged top view diagram illustrating an electronic device according to a fifth embodiment of the present disclosure. Different from the first embodiment, the part 110a of the connection line 110 of this embodiment may include a zigzag pattern, and the zigzag pattern may be formed by upside-down squares that are alternately or periodically arranged, but not limited thereto. The zigzag pattern may also be formed by upside-down triangles that are alternately or periodically arranged. Also, the zigzag pattern may be any line pattern that can alter its extension direction.

The signals output by the gate drivers have different RC loadings when the number of the auxiliary working circuits 108 electrically connected to the auxiliary gate driver 128b is less than the number of the main working circuits 106 electrically connected to the main gate driver 128a. In order to overcome this problem, in some embodiments, the part 110a of the connection line 110 may include the zigzag pattern to increase the length of the connection line 110, and the resistance of the connection line 110 can be adjusted by adjusting the length, thereby reducing the difference in RC loadings of signals in the first portion PO1 and the second portion PO2.

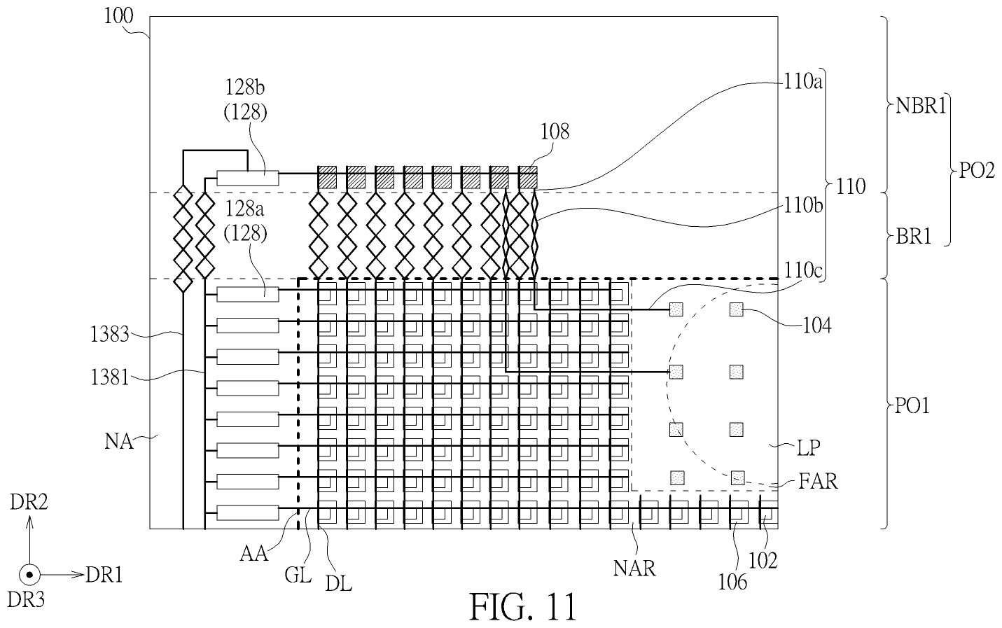

Please refer to FIG. 11, FIG. 11 is a partially enlarged top view diagram illustrating an electronic device according to a sixth embodiment of the present disclosure. For the convenience of illustration, only two connection lines 110 are shown in FIG. 11, but actually each of the auxiliary working circuits 108 can be electrically connected to the corresponding auxiliary electronic unit 104 through one connection line 110. The difference between this embodiment and the first embodiment is that the part 110c of the connection line 110 of the first embodiment (as shown in FIG. 2) is disposed on the functional active region FAR in the first portion PO1 and not on the normal active region NAR in the first portion PO1, but the part 110c of the connection line 110 of this embodiment can be disposed on the normal active region NAR and the functional active region FAR in the first portion PO1.

As shown in FIG. 11, one end of the part 110c may be connected to the part 110b, the part 110c may pass through the normal active region NAR and the functional active region FAR in the first portion PO1, and another end of the part 110c may be electrically connected to the corresponding auxiliary electronic unit 104, but not limited thereto. In this way, the chance of light that passes through the functional active region FAR or passes through the light-transmitting portion LP of the functional active region FAR being blocked by the connection lines 110 can be reduced, thereby improving the imaging effect of the camera.

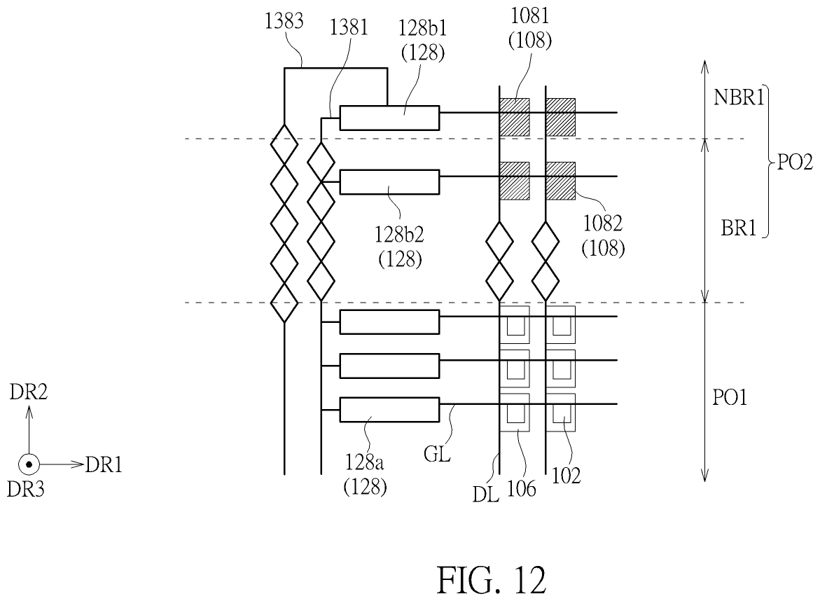

Please refer to FIG. 12, FIG. 12 is a schematic diagram illustrating the positional relationship among main working circuits, auxiliary working circuits, main gate drivers and auxiliary gate drivers according to a seventh embodiment of the present disclosure. The difference between this embodiment and the first embodiment is that at least one auxiliary gate driver 128b1 can be disposed on the first region NBR1 in the second portion PO2 of the substrate 100, and at least one auxiliary gate driver 128b2 can be disposed on the bending region BR1 in the second portion PO2 of the substrate 100, but not limited thereto. In addition, the auxiliary working circuits 1081 electrically connected to the auxiliary gate driver 128b1 can be disposed on the first region NBR1 in the second portion PO2 of the substrate 100, and the auxiliary working circuits 1082 electrically connected to the auxiliary gate driver 128b2 can be disposed on the bending region BR1 in the second portion PO2 of the substrate 100, but not limited thereto.

In some embodiments, as shown in FIG. 12, the signal line 1381 may be electrically connected to the main gate drivers 128a, the auxiliary gate driver 128b1 and the auxiliary gate driver 128b2, and the signal line 1383 may be electrically connected to the auxiliary gate driver 128b1, but not limited thereto.

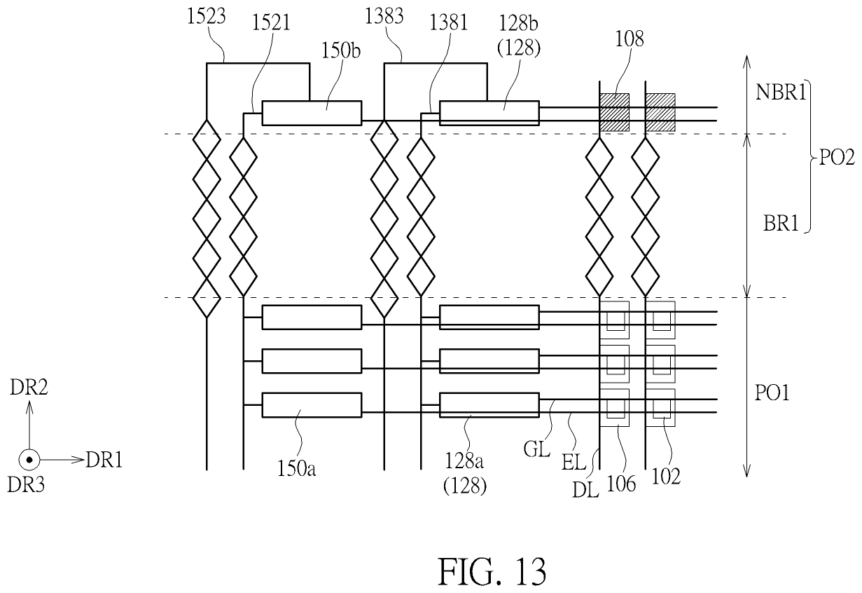

Please refer to FIG. 13, FIG. 13 is a schematic diagram illustrating the positional relationship among main working circuits, auxiliary working circuits, main gate drivers, auxiliary gate drivers, main emission signal drivers and the auxiliary emission signal drivers according to an eighth embodiment of the present disclosure. In some embodiments, the electronic device 1 may be an organic light emitting diode display device, and the electronic device 1 may include a plurality of main emission signal drivers 150a and at least one auxiliary emission signal driver 150b. The main emission signal drivers 150a may be disposed on the first portion PO1 of the substrate 100, and the auxiliary emission signal driver 150b may be disposed on the second portion PO2 of the substrate 100. As shown in FIG. 13, the auxiliary emission signal driver 150b may be disposed on the first region NBR1 in the second portion PO2 of the substrate 100, but not limited thereto. The auxiliary emission signal driver 150b may also be disposed on the bending region BR1 in the second portion PO2 of the substrate 100. In addition, the emission signal driver may include thin film transistors, capacitors or other electronic components, but not limited thereto.

One main emission signal driver 150a can be electrically connected to an emission signal line EL and electrically connected to the corresponding main working circuits 106 through this emission signal line EL, and the main emission signal driver 150a can transmit an emission signal to the main working circuits 106. One auxiliary emission signal driver 150b can be electrically connected to another emission signal line EL and electrically connected to the corresponding auxiliary working circuits 108 through this emission signal line EL, and the auxiliary emission signal driver 150b can transmit an emission signal to the auxiliary working circuits 108.

As shown in FIG. 13, the electronic device 1 may include a signal line 1521 and a signal line 1523. The signal line 1521 may be electrically connected to the main emission signal drivers 150a and the auxiliary emission signal driver 150b, the signal line 1523 may be electrically connected to the auxiliary emission signal driver 150b, and the signal line 1521 and the signal line 1523 may be electrically connected to the chip 130 in FIG. 1, but not limited thereto. The signal line 1521 and the signal line 1523 may include conductive materials such as metals, but not limited thereto. In addition, a portion of the signal line 1521 and a portion of the signal line 1523 disposed on the bending region BR1 may include the anti-crack patterns, but not limited thereto.

As shown in FIG. 13, in some embodiments, the main emission signal driver 150a and the auxiliary emission signal driver 150b can be controlled by the chip 130 to output a first emission signal and a second emission signal. The main emission signal drivers 150a may transmit the first emission signals to the main working circuits 106 through the emission signal lines EL, and the auxiliary emission signal driver 150b may transmit the second emission signal to the auxiliary working circuits 108 through the emission signal line EL, but not limited thereto.

The main working circuit 106 can receive the first data signal (such as the signal DS1, the signal GS1, the first emission signal or combinations thereof) and output the first driving signal TS1 to the main electronic unit 102 according to the first data signal. The auxiliary working circuit 108 can receive the second data signal (such as the signal DS2, the signal GS2, the second emission signal or combinations thereof) and output the second driving signal TS2 to the auxiliary electronic unit 104 according to the second data signal.

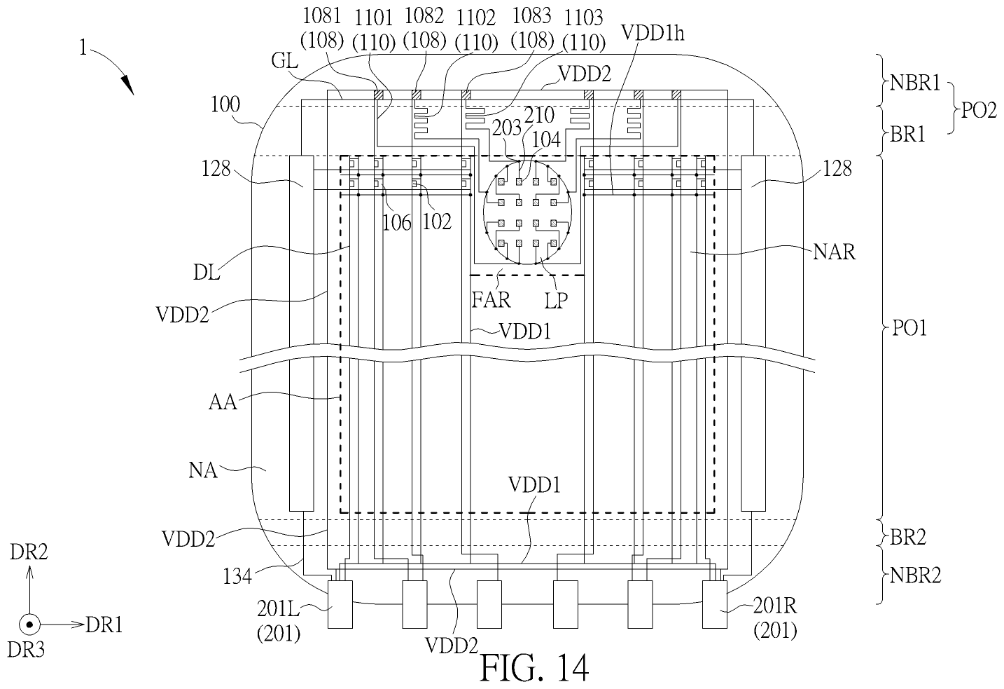

Please refer to FIG. 14, FIG. 14 is a schematic top view diagram illustrating an electronic device according to a ninth embodiment of the present disclosure. In some embodiments, the electronic device 1 may include a plurality of power lines VDD1 and at least one power line VDD2. The power lines VDD1 may extend from the peripheral region NA to the active region AA (for example, extending to the normal active region NAR in the active region AA) In the active region AA, the power lines VDD1 may extend along the direction DR2. One power line VDD1 can be electrically connected to a column of the main working circuits 106, and one end of the power line VDD1 can be electrically connected to a conductive pad 201 and can be electrically connected to a chip (such as the chip 130 in FIG. 1) through the conductive pad 201. In addition, the data lines DL and the signal lines 134 of the gate driving circuits 128 can also be electrically connected to the corresponding conductive pads 201.

In some embodiments, the electronic device 1 may further include a plurality of power lines VDD1h disposed on the active region AA. As shown in FIG. 14, the power lines VDD1h may be disposed on the normal active region NAR in the active region AA. The power lines VDD1h may extend along the direction DR1 and may be electrically connected to the power lines VDD1.

The power line VDD2 is disposed on the peripheral region NA and electrically connected to the auxiliary working circuits 108. In some embodiments, the power line VDD2 can be a closed loop surrounding the active region AA, but not limited thereto. The power line VDD2 can be electrically connected to a row of the auxiliary working circuits 108, the power line VDD2 can also be electrically connected to a conductive pad 201L and a conductive pad 201R, and the power line VDD2 can be electrically connected to the chip through the conductive pad 201L and the conductive pad 201R, but not limited thereto. In addition, the power line VDD2 may be electrically insulated from the power lines VDD1 and the power lines VDD1h, and the voltage of the power line VDD2 may be different from the voltage of the power lines VDD1 and the voltage of the power lines VDD1h. The power lines VDD1 and the power lines VDD1h may have the same voltage.

In some embodiments, a portion of the power line VDD2 may be disposed between the gate driving circuit 128 and the active region AA. For example, a portion of the power line VDD2 may be disposed between the gate driving circuit 128 and the normal active region NAR of the active region AA, thereby reducing the signal coupling phenomenon between the power line VDD2 and the signal lines in the active region AA.

Since the number of the auxiliary electronic units 104 in the functional active region FAR may be less than the number of the main electronic units 102 in the normal active region NAR, the number of the main working circuits 106 electrically connected to the power line VDD1 may be greater than the number of the auxiliary working circuits 108 electrically connected to the power line VDD2. When the main working circuits 106 and the auxiliary working circuits 108 are both electrically connected to identical power lines, the brightness of the main electronic units 102 and the brightness of the auxiliary electronic units 104 may be different due to different quantities.

In some embodiments, since the main working circuits 106 and the auxiliary working circuits 108 are electrically connected to different power lines, different voltages can be transmitted to the main working circuits 106 and the auxiliary working circuits 108 through different power lines (such as the power lines VDD1 and the power line VDD2) to adjust the brightness of the functional active region FAR and the brightness of the normal active region NAR, thereby improving the uniformity the brightness in the active region AA.

In some embodiments, the auxiliary working circuit 108 disposed on the peripheral region NA can be electrically connected to one auxiliary electronic unit 104 on the functional active region FAR through a connection line 110 and a connection line 210. As shown in FIG. 14, the distance between the auxiliary working circuit 1081 and the auxiliary electronic unit 104 electrically connected to the auxiliary working circuit 1081, the distance between the auxiliary working circuit 1082 and the auxiliary electronic unit 104 electrically connected to the auxiliary working circuit 1082, and the distance between the auxiliary working circuit 1083 and the auxiliary electronic unit 104 electrically connected to the auxiliary working circuit 1083 may all be different, thus lengths of the connection lines 110 may also be different and signals may bear different RC loadings.

To overcome the above problem, some of the connection lines 110 may include the zigzag patterns to increase lengths in some embodiments. As shown in FIG. 14, the connection line 1102 and the connection line 1103 may include the zigzag patterns. The zigzag patterns may be disposed on the peripheral region NA, and the zigzag patterns may be formed by left and right inverted squares that are alternately or periodically arranged, but not limited thereto.

In addition, the zigzag patterns may have different lengths, for example, the length of the zigzag pattern of the connection line 1103 may be greater than the length of the zigzag pattern of the connection line 1102. On the other hand, some of the connection lines 110 (such as the connection line 1101 in FIG. 14) may not include the zigzag pattern. Through the design of the zigzag patterns, lengths or areas of the connection lines 110 can be nearly the same, which alleviates the phenomenon that the signals bear different RC loadings and further makes the brightness of the functional active region FAR and the brightness of the normal active region NAR more uniform.

In the functional active region FAR, the light-transmitting portion LP may have an elliptical shape or a circular shape, but the shape is not limited thereto. The auxiliary electronic units 104 and the connection lines 210 may be disposed on the light-transmitting portion LP, and a plurality of connection structures 203 may be disposed on the edge of the light-transmitting portion LP, but not limited thereto. The connection lines 110 and the connection lines 210 may be formed by different conductive layers, and the connection lines 110 and the connection lines 210 may be electrically connected to each other through the connection structures 203. For example, the connection structures 203 may include contact holes formed in an insulating layer, and the connection lines 110 and the connection lines 210 may be electrically connected to each other through the contact holes, but not limited thereto.

The material of the connection lines 110 may include metals, and the material of the connection lines 210 may include transparent conductive materials, but not limited thereto. Since transparent conductive materials are easier to break than metals, the lengths of the connection lines 210 can be shortened and the lengths of the connection lines 110 can be extended by introducing the connection structures 203 on the edge of the light-transmitting portion LP, thereby reducing the chance of breaking the connection line 210.

In some embodiments, the difference in the areas of different connection lines 210 can be reduced by adjusting the widths of the connection lines 210 according to the distances between the connection structures 203 and the auxiliary electronic units 104, thereby alleviating the phenomenon that the signals bear different RC loadings. For example, the connection line 210 may have a thinner width owing to the shorter distance. Therefore, the resistance of the connection line 210 can be increased to be nearly consistent with the resistance of the longer connection line 210.

In some embodiments, a plurality of conductive layers and a plurality of insulating layers may be disposed on the substrate 100. For example, a first conductive layer, a second conductive layer, a third conductive layer, a fourth conductive layer and a fifth conductive layer may be sequentially disposed on the substrate 100 from bottom to top, and the insulating layer may be included between adjacent conductive layers to achieve electrical insulation, but not limited thereto.

The first conductive layer may include the gate lines GL and the signal lines 134, the second conductive layer may include the data lines DL, the third conductive layer may include the power lines VDD1 and the power lines VDD1h, the fourth conductive layer may include the power lines VDD2 and the connection lines 110, the power lines VDD2 may be electrically insulated from the connection lines 110, and the fifth conductive layer may include the connection lines 210, but not limited thereto. The conductive layers may include metal materials, transparent conductive materials, other suitable conductive materials or combinations thereof, but not limited thereto.

For example, the connection structures 203 may include the contact holes disposed in the insulating layer between the fifth conductive layer and the fourth conductive layer, and the connection lines 110 and the connection lines 210 may be electrically connected to each other through the contact holes, but not limited thereto. In addition, the connection lines 110 and/or the connection lines 210 may include conductive pads, and the connection lines 110 and the connection lines 210 may be electrically connected to each other through the conductive pads and the contact holes, but not limited thereto.

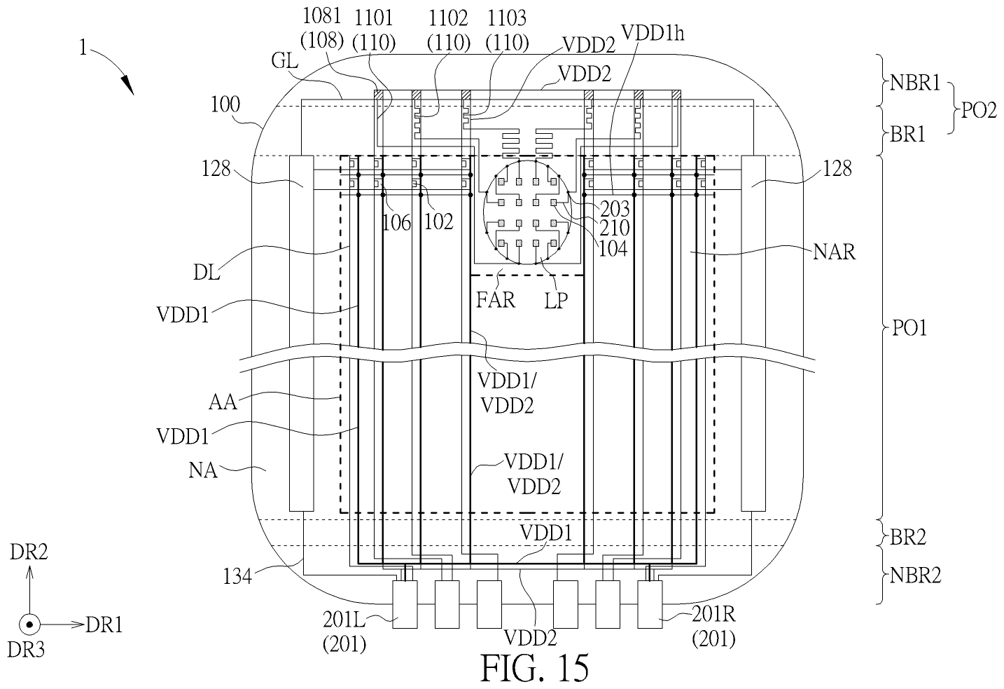

Please refer to FIG. 15, FIG. 15 is a schematic top view diagram illustrating an electronic device according to a tenth embodiment of the present disclosure. Different from the ninth embodiment, the power line VDD2 of this embodiment can be electrically connected to the conductive pad 201L and the conductive pad 201R disposed at the peripheral region NA at the bottom, the power line VDD2 can then extend from the peripheral region NA at the bottom and through the active region AA (for example, through the normal active region NAR in the active region AA) in the direction DR2, and then the power line VDD2 can extend from the active area AA to the peripheral region NA at the top and electrically connect the auxiliary working circuits 108.

A portion of the power line VDD2 may be disposed on the active region AA, and the portion of the power line VDD2 may be overlapped with the power lines VDD1 in the direction DR3. In addition, in the region between the active region AA and the conductive pads 201, the power line VDD2 may be partially overlapped with the power lines VDD1 in the direction DR3. Through the design of the power line VDD2 in this embodiment, the width of the border can be further reduced.

Since the number of the auxiliary electronic units 104 in the functional active region FAR is less than the number of the main electronic units 102 in the normal active region NAR, the brightness of these two regions may be different. In some embodiments, the voltage of the power line VDD2 may be greater than the voltage of the power lines VDD1, thus the brightness of the functional active region FAR can be increased, and the overall brightness of the active region AA can be more uniform. Since the voltage of the power line VDD2 can be greater than the voltage of the power lines VDD1, the width of the power line VDD2 can be designed to be greater than the width of the power line VDD1. For example, the ratio of the width of the power line VDD2 to the width of the power line VDD1 may be greater than or equal to 1 and less than or equal to 1.5, but not limited thereto.

In addition, since the overall resistance of the power lines VDD1 and the power lines VDD1h is relatively low, increasing the width of the power line VDD2 can reduce the resistance of the power line VDD2 and reduce the resistance difference, thus making the brightness of the functional active region FAR and the brightness of the normal active region NAR more uniform.

In addition, since the power lines VDD1 (or the power lines VDD1h) may be close to other conductive lines or electrodes, reducing the width of the power lines VDD1 can increase the distances between the power lines VDD1 and other conductive lines or electrodes, thereby reducing the phenomenon of signal coupling.

In some embodiments, the zigzag pattern of the connection line 1102 may be disposed on the peripheral region NA, but not limited thereto. In the connection line 1103, a portion of the zigzag pattern may be disposed on the peripheral region NA, and another portion of the zigzag pattern may be disposed on the functional active region FAR of the active region AA, but not limited thereto.

Another difference from the ninth embodiment is that a first conductive layer, a second conductive layer, a third conductive layer, a fourth conductive layer, a fifth conductive layer and a sixth conductive layer in this embodiment can be sequentially disposed on the substrate 100 from bottom to top, and the insulating layer may be included between adjacent conductive layers to achieve electrical insulation, but not limited thereto.

The first conductive layer may include the power line VDD2, the second conductive layer may include the gate lines GL and the signal lines 134, the third conductive layer may include the data lines DL, the fourth conductive layer may include the power lines VDD1 and the power lines VDD1h, the fifth conductive layer may include the connection lines 110, and the sixth conductive layer may include the connection lines 210, but not limited thereto.

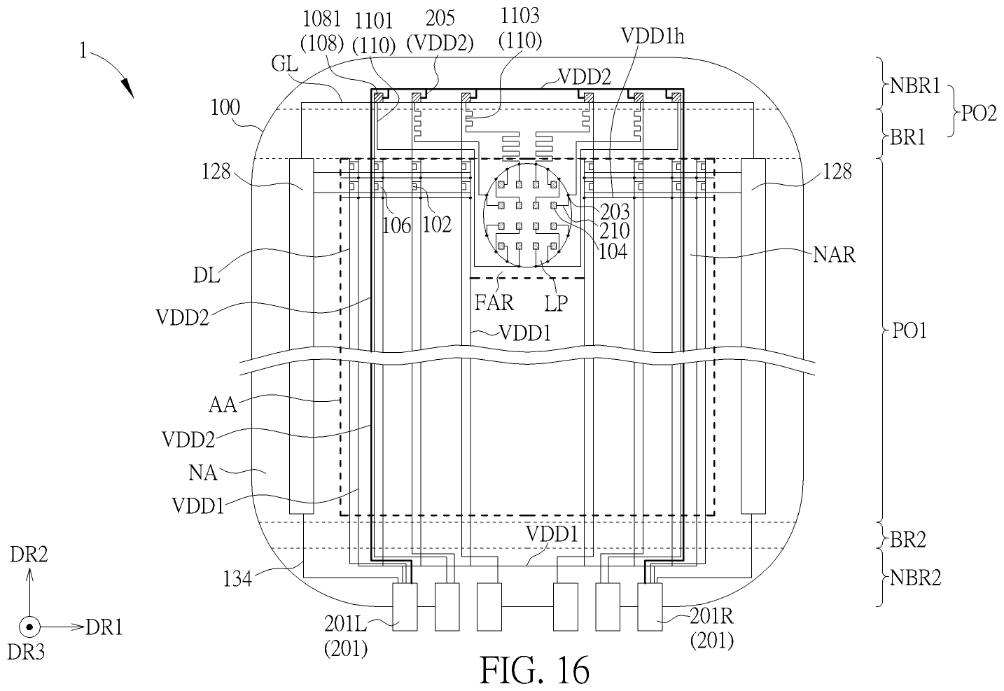

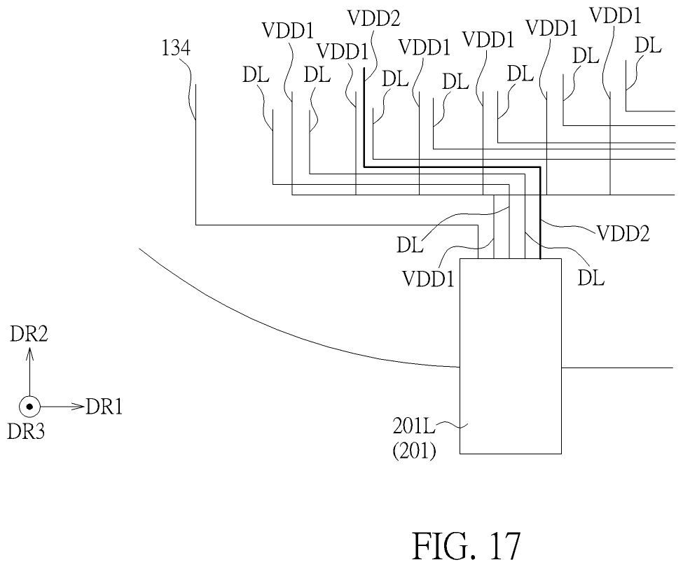

Please refer to FIG. 16 and FIG. 17, FIG. 16 is a schematic top view diagram illustrating an electronic device according to an eleventh embodiment of the present disclosure, and FIG. 17 is an enlarged schematic diagram illustrating the area around the conductive pad according to the eleventh embodiment of the present disclosure. For the convenience of illustration, FIG. 16 only shows part of signal lines and electronic components, and FIG. 17 shows a more complicated connection structure of signal lines. In this embodiment, the power line VDD2 and the data lines DL can be formed by the same conductive layer, but the power line VDD2 is electrically insulated from the data lines DL. One end of the power line VDD2 can be electrically connected to the conductive pad 201L, and the other end of the power line VDD2 can be electrically connected to the conductive pad 201R. The power line VDD2 can extend from the peripheral region NA at the bottom and through the active region AA (for example, through the normal active region NAR in the active region AA) in the direction DR2, and then the power line VDD2 can extend from the active region AA to the peripheral region NA at the top and electrically connect the auxiliary working circuits 108.

In addition, a portion of the power line VDD2 may be disposed on the active region AA, and the portion of the power line VDD2 of this embodiment may not be overlapped with the power lines VDD1 in the direction DR3.

The power line VDD2 of this embodiment may include a plurality of connection line segments 205 disposed on a portion of the peripheral region NA above the active region AA, and the power line VDD2 may be electrically connected to the auxiliary working circuits 108 through the connection line segments 205. The connection line segments 205 may also be formed by the same conductive layer as the data lines DL. Taking the auxiliary working circuit 1081 in FIG. 16 as an example, the data line DL and the connection line segment 205 electrically connected to the auxiliary working circuit 1081 may be disposed on opposite sides of the auxiliary working circuit 1081 in the direction DR1.

The power line VDD2 and the data lines DL can be formed by the same conductive layer, and both of them are electrically connected to the conductive pads 201. Therefore, in some embodiments, one conductive pad 201 may be designed to be electrically connected with one of the power lines VDD2 to reduce signal coupling phenomenon or short circuit phenomenon, but not limited thereto.

In this embodiment, the first conductive layer may include the gate lines GL and the signal lines 134, the second conductive layer may include the data lines DL and the power line VDD2, the third conductive layer may include the power lines VDD1 and the power lines VDD1h, the fourth conductive layer may include the connection lines 110, and the fifth conductive layer may include the connection lines 210, but not limited thereto.

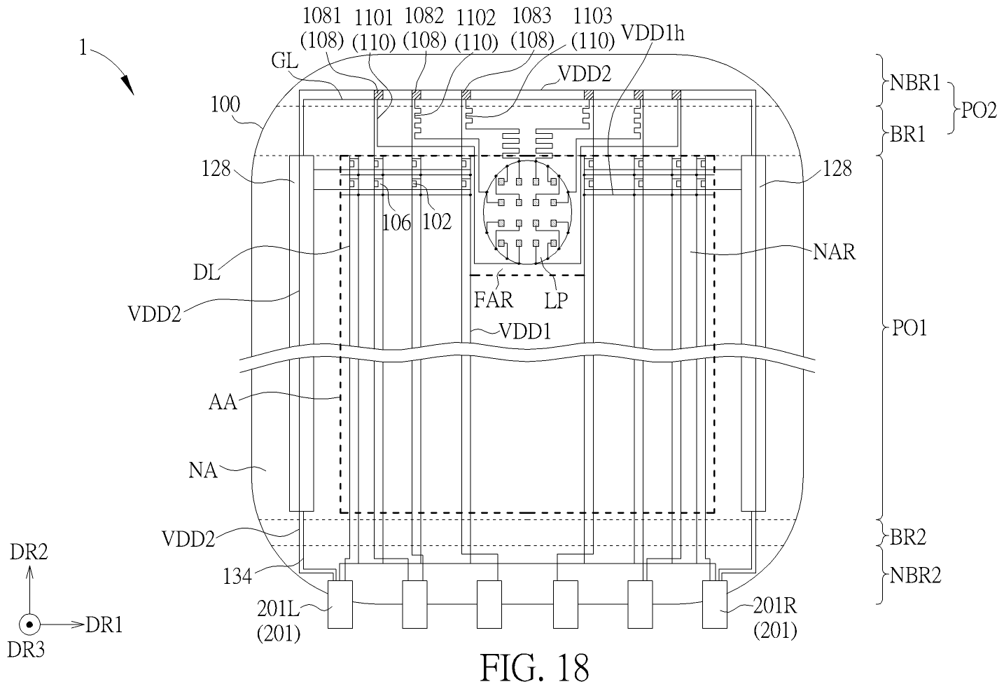

Please refer to FIG. 18, FIG. 18 is a schematic top view diagram illustrating an electronic device according to a twelfth embodiment of the present disclosure. Different from the ninth embodiment, a portion of the power line VDD2 can overlap the gate driving circuit 128 in this embodiment. In addition, in this embodiment, the first conductive layer may include the gate lines GL, the signal lines 134 and the power line VDD2, the second conductive layer may include the data lines DL, the third conductive layer may include the power lines VDD1 and the power lines VDD1h, the fourth conductive layer may include the connection lines 110, and the fifth conductive layer may include the connection lines 210, but not limited thereto.

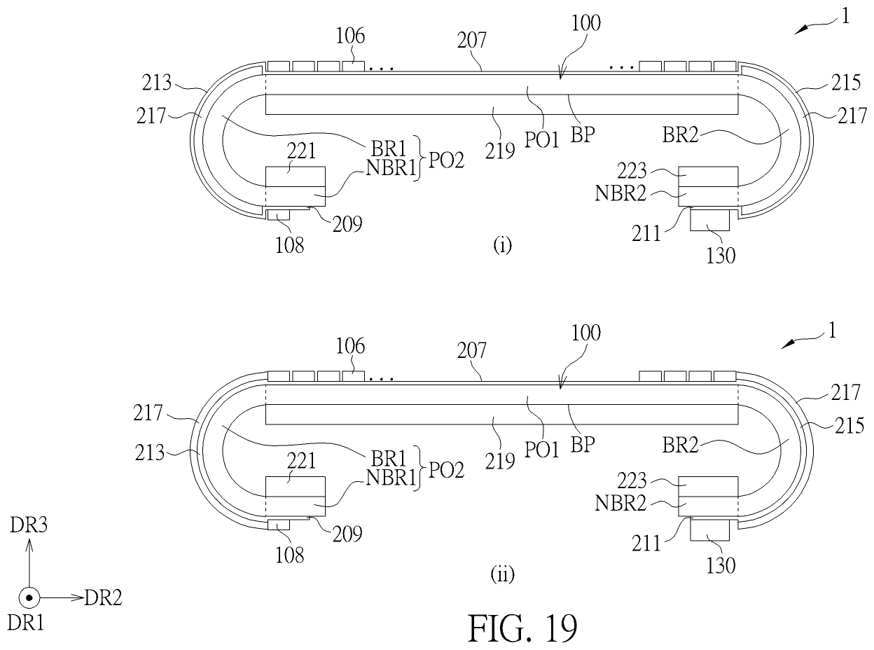

Please refer to FIG. 19, FIG. 19 is a schematic diagram illustrating cross-sectional structures of electronic devices according to some embodiments of the present disclosure. In some embodiments, as shown in example (i) in FIG. 19, one end of a conductive line segment 207 disposed on the first portion PO1 can be electrically connected to a conductive line segment 209 disposed on the first region NBR1 through a conductive line segment 213 disposed on the bending region BR1, and the other end of the conductive line segment 207 can be electrically connected to a conductive line segment 211 disposed on the second region NBR2 through a conductive line segment 215 disposed on the bending region BR2, but not limited thereto.

For example, the conductive line segment 207 can be electrically connected to the main working circuits 106, the conductive line segment 209 can be electrically connected to the auxiliary working circuit 108, and the conductive line segment 211 can be electrically connected to the chip 130, but not limited thereto. For example, the data line DL in the aforementioned embodiment may be a combination of the conductive line segment 207, the conductive line segment 209, the conductive line segment 211, the conductive line segment 213 and the conductive line segment 215, but not limited thereto.

In some embodiments, the conductive line segment 207, the conductive line segment 209 and the conductive line segment 211 may be formed by one conductive layer, and the conductive line segment 213 and the conductive line segment 215 may be formed by another conductive layer, but not limited thereto. In addition, an organic layer 217 may be disposed on the bending region BR1 and the bending region BR2 of the substrate 100, and the conductive line segment 213 and the conductive line segment 215 may be disposed on the organic layer 217. Therefore, the organic layer 217 may be disposed between the conductive line segment 213 and the bending region BR1 of the substrate 100 or between the conductive line segment 215 and the bending region BR2 of the substrate 100.

For example, the conductive line segment 213 can be electrically connected to the conductive line segment 207 and the conductive line segment 209 through contact holes in the organic layer 217, and the conductive line segment 215 can be electrically connected to the conductive line segment 207 and the conductive line segment 211 through contact holes in the organic layer 217, but not limited thereto.

The electronic device 1 may further include a supporting film 219, a supporting film 221 and a supporting film 223 disposed at a bottom surface BP of the substrate 100. The supporting film 219 may be disposed corresponding to the first portion PO1 of the substrate 100, the supporting film 221 may be disposed corresponding to the first region NBR1 of the substrate 100, and the supporting film 223 may be disposed corresponding to the second region NBR2 of the substrate 100. The bending region BR1 and the bending region BR2 of the substrate 100 may not be correspondingly provided with supporting films. The supporting film can be flexible and can have higher hardness than the substrate 100. For example, the thicknesses of the supporting films may be greater than the thickness of the substrate 100 when the supporting films and the substrate 100 include the same material. In some embodiments, the supporting films and the substrate 100 may include different materials. The materials of the supporting films may include polyimide (PI), polycarbonate (PC), polyethylene terephthalate (PET), other suitable materials, or combinations thereof, but not limited thereto.

As shown in example (ii) in FIG. 19, the conductive line segment 207, the conductive line segment 209, the conductive line segment 211, the conductive line segment 213 and the conductive line segment 215 may be formed by the same conductive layer. The conductive line segment 213 may be disposed between the organic layer 217 and the bending region BR1 of the substrate 100, and the conductive line segment 215 may be disposed between the organic layer 217 and the bending region BR2 of the substrate 100.

To sum up, in the electronic device of the present disclosure, the auxiliary electronic units can be disposed on the functional active region of the substrate, the auxiliary working circuits electrically connected to the auxiliary electronic units can be disposed on the second portion of the substrate, thus the chance of light that passes through the functional active region or passes through the light-transmitting portion of the functional active region being blocked by the circuits can be reduced, thereby improving the imaging effect of the camera. The main working circuits and the auxiliary working circuits can be electrically connected to different power lines, thus the brightness of the functional active region and the brightness of the normal active region can be adjusted by providing different voltages to the main working circuits and the auxiliary working circuits through different power lines, and the overall brightness of the active region can be more uniform. In addition, the second portion of the substrate can be bent with respect to the first portion of the substrate through the bending region of the second portion, thus the width of the border can be further reduced to achieve narrow border design or borderless design.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. An electronic device, comprising:
a substrate comprising a first portion and a second portion bent with respect to the first portion, wherein the first portion has a normal active region and a functional active region;
a main electronic unit disposed on the normal active region;
an auxiliary electronic unit disposed on the functional active region;
a main working circuit disposed on the first portion and electrically connected to the main electronic unit, wherein the main working circuit is configured to receive a first data signal and output a first driving signal to the main electronic unit according to the first data signal; and
an auxiliary working circuit disposed on the second portion and electrically connected to the auxiliary electronic unit, wherein the auxiliary working circuit is configured to receive a second data signal and output a second driving signal to the auxiliary electronic unit according to the second data signal.

2. The electronic device according to claim 1, wherein the auxiliary working circuit is electrically connected to the auxiliary electronic unit through a connection line, and a part of the connection line is disposed on the first portion and another part of the connection line is disposed on the second portion.

3. The electronic device according to claim 2, wherein the connection line comprises a first layer and a second layer, the first layer is at least disposed on the first portion, the second layer is at least disposed on the second portion, the first layer comprises a transparent conductive material, and the second layer comprises a metal material.

4. The electronic device according to claim 3, wherein the first layer is connected to the second layer at a position near a boundary between the first portion and the second portion.

5. The electronic device according to claim 3, wherein the second portion has a bending region with a first length, the first layer further has a portion disposed on the bending region, the portion of the first layer has a second length, and a ratio of the second length to the first length is less than or equal to 0.5.

6. The electronic device according to claim 2, wherein the second portion has a bending region, the connection line has a portion disposed on the bending region, and the portion comprises an anti-crack pattern.

7. The electronic device according to claim 2, further comprising another auxiliary electronic unit, another auxiliary working circuit, and another connection line, wherein the another auxiliary working circuit is electrically connected to the another auxiliary electronic unit through the another connection line, and the connection line and the another connection line are adjacent to each other and comprise different layers.

8. The electronic device according to claim 2, wherein the another part of the connection line comprises a zigzag pattern.

9. The electronic device according to claim 2, wherein the part of the connection line is disposed on the normal active region of the first portion.

10. The electronic device according to claim 1, wherein the second portion has a bending region and a first region, the bending region is disposed between the first region and the normal active region, and the auxiliary working circuit is disposed on the first region.

11. The electronic device according to claim 1, wherein a part of the second portion is overlapped with the first portion in a normal direction of a surface of the first portion.

12. The electronic device according to claim 1, wherein the second portion is not overlapped with the first portion in a normal direction of a surface of the first portion.

13. The electronic device according to claim 1, further comprising a main gate driver disposed on the first portion and an auxiliary gate driver disposed on the second portion, wherein the main gate driver is electrically connected to the main working circuit and the auxiliary gate driver is electrically connected to the auxiliary working circuit.

14. The electronic device according to claim 13, wherein the second portion has a bending region and a first region, the bending region is disposed between the first region and the normal active region, and the auxiliary gate driver is disposed on the first region.

15. The electronic device according to claim 13, wherein the auxiliary gate driver has an auxiliary output thin film transistor and the main gate driver has a main output thin film transistor, and a ratio of a channel width to a channel length of the auxiliary output thin film transistor is less than a ratio of a channel width to a channel length of the main output thin film transistor.

16. The electronic device according to claim 1, wherein the substrate further comprises an active region and a peripheral region disposed on at least one side of the active region, the active region comprises the normal active region and the functional active region, and the electronic device further comprises:
a first power line extending from the peripheral region to the active region and electrically connected to the main working circuit; and
a second power line disposed on the peripheral region and electrically connected to the auxiliary working circuit,
wherein the first power line is electrically insulated from the second power line, and a voltage of the first power line is different from a voltage of the second power line.

17. The electronic device according to claim 16, further comprising a gate driving circuit disposed on the peripheral region, wherein a portion of the second power line is disposed between the gate driving circuit and the normal active region.

18. The electronic device according to claim 16, further comprising a gate driving circuit disposed on the peripheral region, wherein a portion of the second power line overlaps the gate driving circuit.

19. The electronic device according to claim 16, wherein a portion of the second power line is disposed on the active region, and the portion of the second power line is overlapped with the first power line.

20. The electronic device according to claim 16, wherein a portion of the second power line is disposed on the active region, and the portion of the second power line is not overlapped with the first power line.
